(19) United States
(12) Patent Application Publication
(10) Pub. No.: US 2005/0037620 A1
(43) Pub. Date: Feb. 17, 2005

(54) Method for achieving wafer contact for electro-processing

(76) Inventors: Michael J. Berman, West Linn, OR (US); Steven E. Reder, Boring, OR (US)

Correspondence Address: LSI LOGIC CORPORATION, 1621 BARBER LANE, MS: D-106, MILPITAS, CA, 95035, US

(21) Appl. No.: 10/641,811

(22) Filed: Aug. 15, 2003

(51) Int. Cl. H01L 21/326

(52) U.S. Cl. 438/692; 438/466

(57) ABSTRACT

A conductive type of seed or process film is used to cover the front side, the side, and at least a portion of the back side of a semiconductor wafer. The portion of the film which is on the back side of the wafer acts as contact for the electro-plating or electro-polishing process, thereby obviating the need for any front side contact. During the electro-process, the wafer can be positioned on a backing plate which supports the wafer as well as contacts which engage at least a portion of the conductive layer on the back side of the wafer. In depositing the conductive seed or process film, the wafer is positioned on a pedestal which has a diameter that is smaller than a diameter of the wafer. The difference in the pedestal and wafer diameters then becomes the area where the conductive seed or process film covers the back side of the wafer. The conductive film can be easily removed during subsequent wafer processing.

### BACKGROUND

The present invention generally relates to methods and apparatuses for processing, such as electroplating or electro-polishing, a semiconductor wafer, and more specifically relates to a method and apparatus for achieving wafer contact in a process, such as an electroplating or electro-polishing process.

In many semiconductor fabrication process steps, such as electro-plating or electro-polishing (either of which are hereafter referred to as “electro-processing”), there is a need for good electrical contact to the front side of the semiconductor wafer. This contact is necessary for a complete electrical circuit to be made for the process, such as an electro-plating or electro-polishing process, to be effective. In other words, a front side contact (i.e., contact to the device side of the wafer) must be made to enable the process to function.

Contacting a semiconductor wafer on its front side in a process, such as in an electro-process, presents several problems. Currently, many different methods are in use to achieve front side contact to the conductive film. In fact, many different vendors have their own proprietary method for making contact. Generally, the methods which are widely practiced provide that the edge die (i.e., the die disposed proximate the edge of the wafer) are impacted. Depending on the tool set-up, a certain degree of wafer edge exclusion is created. Additionally, front side contact often presents an interference problem during processing, due to processing not be able to occur in the area of contact. Furthermore, a contact ring is often used to hold the wafer, and the edge of some of the die are often impacted by the contact ring. Process uniformity is also affected in the proximity of the contact ring.

### OBJECTS AND SUMMARY

An object of an embodiment of the present invention is to provide a method and apparatus which avoids having to make front side contact with a wafer during processing, such as electro-processing.

Another object of an embodiment of the present invention is to provide a method and apparatus which reduces defect density in electro-processing a semiconductor wafer.

Still another object of an embodiment of the present invention is to provide a method and apparatus which provides that no die are damaged on the front side of a semiconductor wafer during electro-processing.

Still yet another object of an embodiment of the present invention is to provide a method and apparatus which provides that a final edge clean step can be less encroaching due to reduced front side damage of a semiconductor wafer during electro-processing.

Briefly, and in accordance with at least one of the foregoing objects, an embodiment of the present invention provides a method and apparatus which uses a conductive type of seed or process film that covers the front side, the side, and at least a portion of the back side of a semiconductor wafer. The portion of the film which is on the back side of the wafer acts as contact for the electro-plating or electro-polishing process, thereby obviating the need for any front side contact. During the electro-process, the wafer can be positioned on a backing plate which supports the wafer as well as contacts (i.e., the part of the chuck or head that holds the wafer, making contact with the metal or conductive layer on the back side of the wafer). A wear ring may also be used to hold the wafer.

In depositing the conductive seed or process film, the wafer is positioned on a pedestal which has a diameter that is smaller than a diameter of the wafer. The pedestal may or may not utilize lift pin technology to load and unload the wafer. The difference in the pedestal and wafer diameters then becomes the area where the conductive seed or process film covers the back side of the wafer. Thereafter, this portion can be used as the contact area, thereby obviating the need for front side contact. The conductive film can be easily removed during subsequent processing steps.

### BRIEF DESCRIPTION OF THE DRAWINGS

The organization and manner of the structure and operation of the invention, together with further objects and advantages thereof, may best be understood by reference to the following description, taken in connection with the accompanying drawing, wherein:

FIG. 1 illustrates a wafer positioned on a pedestal and engaged in an electro-process, consistent with the prior art;

FIG. 2 illustrates a wafer positioned on a pedestal, consistent with an embodiment of the present invention;

FIG. 3 illustrates the wafer of FIG. 2 engaged in an electro-process;

FIG. 4 provides a block diagram which illustrates the steps of a method of forming the wafer shown in FIG. 2, and implementing the wafer in an electro-process (as referred to in connection with FIG. 3).

### DESCRIPTION

While the invention may be susceptible to embodiment in different forms, there is shown in the drawings, and herein will be described in detail, a specific embodiment with the understanding that the present disclosure is to be considered an exemplification of the principles of the invention, and is not intended to limit the invention to that as illustrated and described herein.

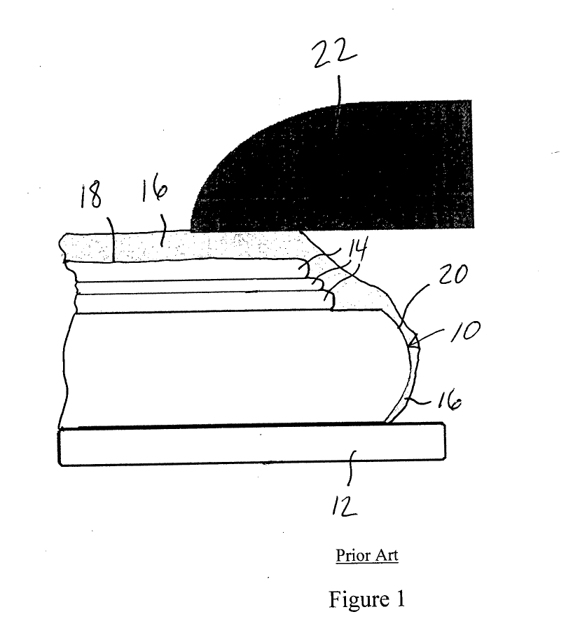

FIG. 1 illustrates a wafer 10 positioned on a pedestal 12 and engaged in an electro-process, consistent with the prior art. The wafer 10 includes a plurality of film layers 14 and a CVD-type film 16 over the front side 18 and along the side edge 20, for use as an electrical contact for electro-processing (also used as a seed or barrier layer for the copper film). The pedestal 12 is wider than the wafer 10, such that the side edge 20 of the wafer 10 does not hang off the pedestal 12, and a clamp 22 engages the front side 18 of the wafer 10 (i.e, technically the film 16 on the front side 18 of the wafer 10) for electro-processing. As discussed above, contacting the front side of the wafer 10 presents many disadvantages.

In contrast, the present invention avoids having to make front side contact with a wafer during processing, such as electro-processing, thereby reducing defect density, providing that no die are damaged, and providing that a final edge clean step can be less encroaching.

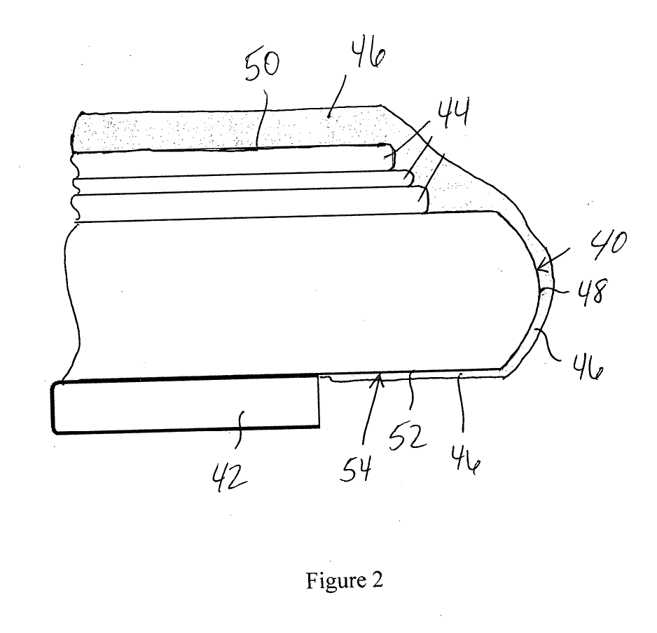

FIG. 2 illustrates a wafer 40 positioned on a pedestal 42, consistent with an embodiment of the present invention. The wafer 40 includes a plurality of film layers 44 and a conductive layer such as a CVD-type film or seed layer 46. As shown, the wafer 40 is wider than the pedestal 42 (i.e., the pedestal 42 has a smaller diameter than does the wafer 40), such as by a few millimeters, such that the side edge 48 of the wafer 10 hangs over the edge of the pedestal 42. The fact that the wafer 40 is wider than the pedestal 42 provides that when a CVD-type, CVD-type conductive film or seed layer 46 is deposited, the layer 46 covers not only the front side of the wafer 50, and the side edge 48, but also at least a portion of a back side 52 of the wafer 40 (i.e., the portion 54 that is left exposed by the pedestal 42). Preferably, the portion of the film 46 which is disposed on the back side 52 of the wafer 40 is 2 millimeters wide or more. The CVD-type film 46 is used as an electrical contact in an electro-processing process (also used as a seed or barrier layer for the copper film). The conductive film 46 can be easily removed after the next level of subsequent processing on the wafer 40 (i.e., before there are any of the oxide mask/etch steps). Preferably, the processing tool has an edge bevel and a back side clean module to remove the films after processing is complete.

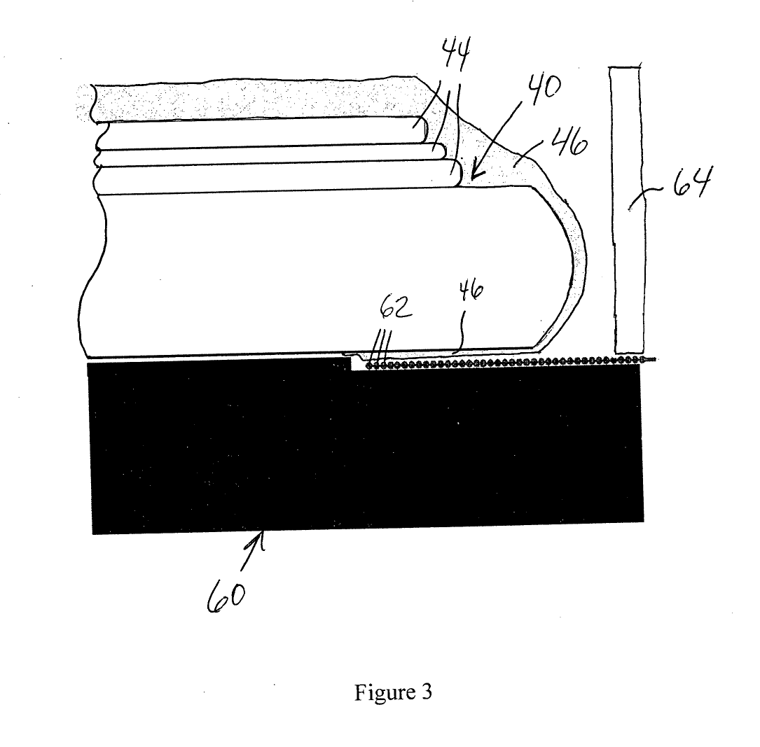

FIG. 3 illustrates the wafer 40 of FIG. 2 engaged in such an electro-process. As shown, a backing plate 60 supports the wafer 40 as well as backside contacts 62 (this is the part of the chuck or head that holds the wafer, making contact with the metal on the back side of the wafer). A wear ring 64 would hold the wafer in use with a CMP-type process. Wear ring 64 obviously would not be used for an electro-polishing or electro-plating operation.

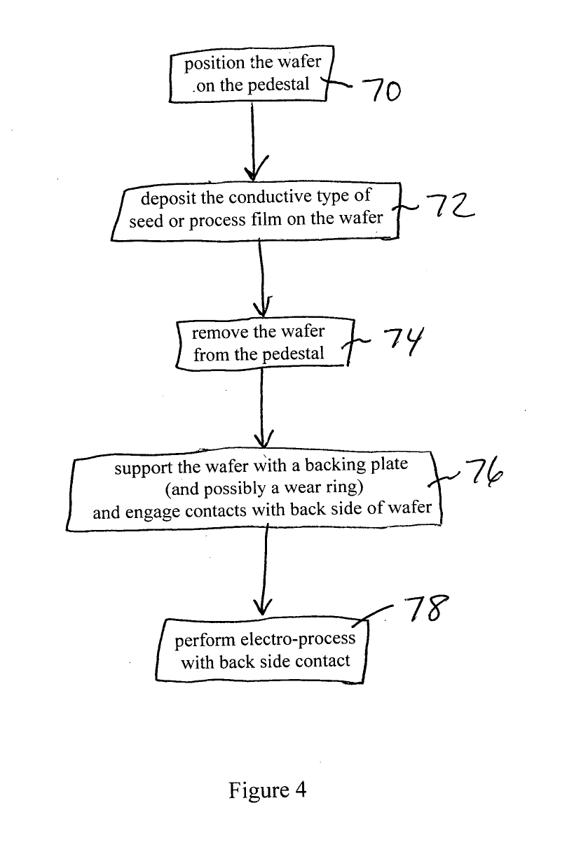

As shown in FIG. 4, to make the wafer shown in FIG. 2, the steps include (among other steps not specifically shown, but readily understood by one having ordinary skill in the art): positioning the wafer on the pedestal (box 70) and depositing the conductive type of seed or process film on the wafer (box 72). Then, the wafer is removed from the pedestal (box 74). Then, to employ the wafer in an electro-process, the wafer is supported by a backing plate, as well as possibly a wear ring (box 76). Finally, the electro-process takes place (box 78).

The present invention obviates the need to contact the front side of a semiconductor wafer in an electro-process, thereby reducing defect density, as well as providing that no die are damaged and that a final edge clean step can be less encroaching. The present invention can be used in connection with electro-polishing, electroplating, scrubbing, CMP or any other process that would otherwise require front side wafer contact for processing to occur.

While an embodiment of the present invention is shown and described, it is envisioned that those skilled in the art may devise various modifications of the present invention without departing from the spirit and scope of the appended claims.

1. A method of forming a semiconductor wafer, said wafer having a front side, as least one side edge, and a back side which is opposite said front side, said method comprising: positioning the wafer on a pedestal such that the side edge of said wafer hangs over an edge of said pedestal and at least a portion of the back side of said wafer contacts said pedestal; and depositing a conductive layer on said front side, side edge, and at least a portion of said back side of said wafer.

2. A method as recited in claim 1, further comprising positioning said wafer on a backing plate, said backing plate supporting contacts, and engaging at least a portion of the conductive layer on said back side of said wafer with said contacts.

3. A method as recited in claim 2, wherein said step of depositing a conductive layer comprises depositing a conductive film.

4. A method as recited in claim 2, further comprising engaging at least a portion of the conductive layer on said back side of said wafer with contacts.

5. A method as recited in claim 2, further comprising removing said wafer from said pedestal.

6. A method as recited in claim 2, wherein the step of depositing a conductive layer on said front side, side edge, and at least a portion of said back side of said wafer comprises depositing at least 2 millimeters of said conductive layer on said back side of said wafer.

7. A method as recited in claim 2, further comprising employing a wear ring.

8. A wafer for use in an electro-process, said wafer comprising: a front side, a side edge, and a back side; and a conductive layer on said front side, said side edge, and at least a potion of said back side.

9. A wafer as recited in claim 8, wherein the conductive layer comprises a conductive film.

10. A wafer as recited in claim 8, wherein the conductive layer is at least 2 millimeters wide on the back side of the wafer.

11. An electro-processing system comprising: a wafer which comprises a front side, a side edge, a back side; and a conductive layer on said front side, said side edge, and at least a potion of said back side; and contacts configured to engage the conductive layer on the back side of the wafer.

12. An electro-processing system as recited in claim 11, further comprising a backing plate configured to support said contacts and said wafer, wherein said conductive layer on the back side of said wafer engages said contacts.

13. An electro-processing system as recited in claim 11, further comprising a wear ring configured to engage the wafer.
